(19) United States
(12) Patent Application Publication
(10) Pub. No.: US 2026/0117033 A1
(43) Pub. Date: Apr. 30, 2026

(54) POLYAMIDE-IMIDE-BASED FILM, PREPARATION METHOD THEREOF, AND COVER WINDOW AND DISPLAY DEVICE COMPRISING THE SAME

(71) Applicant: SK microworks solutions Co., Ltd., Chungcheongnam-do (KR)

(72) Inventors: Jin Woo LEE, Chungcheongnam-do (KR); Jin Yong LEE, Chungcheongnam-do (KR); Yun-Hee SEO, Chungcheongnam-do (KR); Dawoo JEONG, Chungcheongnam-do (KR); Ki Youn SONG, Chungcheongnam-do (KR)

(21) Appl. No.: 19/354,862

(22) Filed: Oct. 10, 2025

(30) Foreign Application Priority Data
Oct. 25, 2024 (KR) 10-2024-0147922

(51) Int. Cl. C08J 5/18; C08G 73/14; H05K 5/03

(52) U.S. Cl. CPC C08J 5/18; C08G 73/14; H05K 5/03; C08J 2379/08

(57) ABSTRACT

The embodiments aim to provide a polyamide-imide-based film, which comprises a polyamide-imide-based polymer that is free of fluorine atoms and which has a modulus of 5 GPa or more based on a film thickness of 50 μm, whereby it is excellent in optical properties, mechanical properties, and ultraviolet ray blocking rates; a process for preparing the same; and a cover window and a display device comprising the same.

### CROSS-REFERENCE TO RELATED APPLICATION

The present application claims the benefit of Korean Patent Application number 10-2024-0147922, filed on Oct. 25, 2024, which is incorporated herein by reference in its entirety.

### TECHNICAL FIELD

Embodiments relate to a polyamide-imide-based film, to a process for preparing the same, and to a cover window and a display device comprising the same.

### BACKGROUND ART

Polyimide-based resins such as poly(amide-imide) (PAI) are excellent in resistance to friction, heat, and chemicals. Thus, they are employed in such applications as primary electrical insulation, coatings, adhesives, resins for extrusion, heat-resistant paintings, heat-resistant boards, heat-resistant adhesives, heat-resistant fibers, and heat-resistant films.

Polyimide is used in various fields. For example, polyimide is made in the form of a powder and used as a coating for metals or magnetic wires. It is mixed with other additives depending on the applications thereof. Further, polyimide is used to coat kitchenware, used as a membrane for gas separation by virtue of its thermal resistance and chemical resistance, and used in natural gas wells for filtration of such contaminants as carbon dioxide, hydrogen sulfide, and impurities.

In recent years, polyimide has been developed in the form of a film, which is less expensive and has excellent optical, mechanical, and thermal characteristics. Such a polyimide-based film may be applied to display materials for organic light-emitting diodes (OLEDs) or liquid crystal displays (LCDs), and the like, and to antireflection films, compensation films, and retardation films if retardation properties are implemented.

However, conventional polyimide-based films, specifically, conventional polyamide-imide-based films, have a problem in that polyamide-imide-based polymers necessarily contain a fluorine atom, which may be subject to environmental regulations. Accordingly, the demand for the development of polyamide-imide-based films that are prepared from a fluorine-free polyamide-imide-based polymer and have excellent optical properties and mechanical properties is steadily increasing.

### DETAILED DESCRIPTION OF THE INVENTION

### Technical Problem

The embodiments aim to provide a polyamide-imide-based film having excellent optical properties and mechanical properties, a process for preparing the same, and a cover window and a display device comprising the same.

### Solution to the Problem

The polyamide-imide-based film according to an embodiment comprises a polyamide-imide-based polymer that is free of fluorine atoms, wherein the polyamide-imide-based film has a modulus of 5 GPa or more based on a film thickness of 50 μm.

The cover window for a display device according to another embodiment comprises a polyamide-imide-based film and a functional layer, wherein the polyamide-imide-based film comprises a polyamide-imide-based polymer that is free of fluorine atoms, and the polyamide-imide-based film has a modulus of 5 GPa or more based on a film thickness of 50 μm.

The display device according to another embodiment comprises a display unit; and a cover window disposed on the display unit, wherein the cover window comprises a polyamide-imide-based film and a functional layer, the polyamide-imide-based film comprises a polyamide-imide-based polymer that is free of fluorine atoms, and the polyamide-imide-based film has a modulus of 5 GPa or more based on a film thickness of 50 μm.

The process for preparing the polyamide-imide-based film according to an embodiment comprises polymerizing a diamine compound, a dianhydride compound, and a dicarbonyl compound in an organic solvent to prepare a polyamide-imide-based polymer solution; casting the solution and drying it to prepare a gel sheet; and thermally treating the gel sheet.

### Advantageous Effects of the Invention

The polyamide-imide-based film according to an embodiment has excellent optical properties and mechanical properties even though the polyamide-imide-based polymer is free of fluorine atoms.

In addition, since the polyamide-imide-based film according to an embodiment is free of fluorine atoms, it can easily comply with environmental regulations.

Further, the polyamide-imide-based film according to an embodiment has excellent UV blocking rates; thus, when it is applied to a display device, it prevents the deterioration or damage caused by UV rays, thereby maintaining stable performance of the display device even after long-term use.

### BRIEF DESCRIPTION OF THE DRAWINGS

FIG. 1 is a schematic exploded view of a display device according to an embodiment.

FIG. 2 is a schematic perspective view of a display device according to an embodiment.

FIG. 3 is a schematic cross-sectional view of a display device according to an embodiment.

FIG. 4 is a schematic flow diagram of a process for preparing a polyamide-imide-based film according to an embodiment.

### BEST MODE FOR CARRYING OUT THE INVENTION

Hereinafter, the embodiments will be described in detail with reference to the accompanying drawings so that those skilled in the art to which the present invention pertains may easily practice them. However, the embodiments may be implemented in many different ways and are not limited to those described herein.

Throughout the present specification, in the case where each film, window, panel, layer, or the like is mentioned to be formed “on” or “under” another film, window, panel, layer, or the like, it means not only that one element is directly formed on or under another element, but also that one element is indirectly formed on or under another element with other element(s) interposed between them. In addition, the term on or under with respect to each element may be referenced to the drawings. For the sake of description, the sizes of individual elements in the appended drawings may be exaggeratedly depicted and do not indicate the actual sizes. In addition, the same reference numerals refer to the same elements throughout the specification.

Throughout the present specification, when a part is referred to as “comprising” an element, it is understood that other elements may be comprised, rather than other elements are excluded, unless specifically stated otherwise.

In the present specification, a singular expression is interpreted to cover a singular or plural number that is interpreted in context unless otherwise specified.

In addition, all numbers and expressions related to the quantities of components, reaction conditions, and the like used herein are to be understood as being modified by the term “about,” unless otherwise indicated.

The terms first, second, and the like are used herein to describe various elements, and the elements should not be limited by the terms. The terms are used only for the purpose of distinguishing one element from another.

In addition, the term “substituted” as used herein means to be substituted with at least one substituent group selected from the group consisting of deuterium, —F, —Cl, —Br, —I, a hydroxyl group, a cyano group, a nitro group, an amino group, an amidino group, a hydrazine group, a hydrazone group, an ester group, a ketone group, a carboxyl group, a substituted or unsubstituted alkyl group, a substituted or unsubstituted alkenyl group, a substituted or unsubstituted alkynyl group, a substituted or unsubstituted alkoxy group, a substituted or unsubstituted alicyclic organic group, a substituted or unsubstituted heterocyclic group, a substituted or unsubstituted aryl group, and a substituted or unsubstituted heteroaryl group. The substituent groups enumerated above may be connected to each other to form a ring.

### Polyamide-Imide-Based Film

An embodiment provides a polyamide-imide-based film that has excellent optical properties such as yellow index and haze, as well as excellent mechanical properties and UV blocking rates.

The polyamide-imide-based film according to an embodiment comprises a polyamide-imide-based polymer that is free of fluorine atoms, wherein the polyamide-imide-based film has a modulus of 5 GPa or more based on a film thickness of 50 μm.

Specifically, the presence of fluorine atoms in the polyamide-imide-based polymer may not be detected when analyzed by scanning electron microscope-energy dispersive X-ray spectroscopy (SEM-EDS). For example, the presence of fluorine atoms in the polyamide-imide-based polymer may not be detected when analyzed by SEM-EDS using a FlatQUAD XFlash 150 device from Bruker.

In an embodiment, the polyamide-imide-based film may be substantially free of fluorine atoms.

Specifically, the polyamide-imide-based film may contain fluorine atoms in an amount of 500 ppm or less.

More specifically, the polyamide-imide-based film may contain fluorine atoms in an amount of 400 ppm or less, 300 ppm or less, 200 ppm or less, 100 ppm or less, or 50 ppm or less.

For example, the polyamide-imide-based film may be free of fluorine atoms, but it is not limited thereto.

When the polyamide-imide-based film and/or the polyamide-imide-based polymer according to an embodiment is free of fluorine atoms or contains fluorine atoms in the above range, it is possible to provide an environmentally friendly film by minimizing the amount of hazardous substances contained in the film, the lifespan of the film can be extended by improving chemical stability, and it can be free from environmental regulations related to fluorine (PFAS).

In an embodiment, the polyamide-imide-based film may have a modulus of 5.2 GPa or more, 5.3 GPa or more, 5.4 GPa or more, 5.5 GPa or more, 5.6 GPa or more, 5.7 GPa or more, 5.8 GPa or more, 5.9 GPa or more, or 6 GPa or more, and 8 GPa or less, 7.5 GPa or less, or 7 GPa or less, based on a film thickness of 50 μm.

Specifically, the modulus of the polyamide-imide-based film may be 5 to 8 GPa, 5 to 7 GPa, 5.4 to 8 GPa, 5.4 to 7 GPa, 6 to 8 GPa, or 6 to 7 GPa, based on a film thickness of 50 μm.

When a sample is cut to 10 cm or more in a direction perpendicular to the main shrinkage direction and 10 mm in the main shrinkage direction, mounted on clips at an interval of 10 cm, and then stretched at room temperature at a rate of 10 mm/minute until fracture occurs to obtain a stress-strain curve, the slope of the load for the initial deformation in the stress-strain curve may be taken as the modulus (GPa). For example, the modulus may be measured using a universal testing machine UTM 5566A from Instron, but it is not limited thereto.

When the modulus of the polyamide-imide-based film according to an embodiment satisfies the above range, the mechanical strength and durability of the polyamide-imide-based film are enhanced, the thermal resistance of the film is improved, and the film may be suitable for use in electronic device components such as cover windows.

On the other hand, if the modulus of the polyamide-imide-based film according to an embodiment does not satisfy the above range, there is a possibility that the film may be deformed by heat or external force, or the moldability may be deteriorated during processing.

In an embodiment, the polyamide-imide-based film may have a transmittance of 3% or less at a wavelength of 380 nm based on a film thickness of 50 μm. Specifically, the transmittance of the polyamide-imide-based film at a wavelength of 380 nm may be 2.5% or less, 2.3% or less, 2% or less, 1.7% or less, 1.5% or less, 1% or less, 0.7% or less, 0.5% or less, 0.4% or less, 0.35% or less, or 0.3% or less, based on a film thickness of 50 μm.

For example, the transmittance at a wavelength of 380 nm may be measured using a UV/visible/near-infrared spectrophotometer V-670 from JASCO, but it is not limited thereto.

When the transmittance of the polyamide-imide-based film according to an embodiment at a wavelength of 380 nm satisfies the above range, the UV blocking rates increase, thereby enhancing the optical stability of the film, and the film can be suitably used for protecting electronic device components and displays that are sensitive to UV rays. On the other hand, if the transmittance of the polyamide-imide-based film according to an embodiment at a wavelength of 380 nm does not satisfy the above range, there is a possibility that ultraviolet rays may cause the discoloration of the material and the deterioration of physical properties.

In an embodiment, the polyamide-imide-based film does not comprise a UV blocking agent.

According to an embodiment, the polyamide-imide-based film may have a total light transmittance of 78% or more or 80% or more as measured in the visible light wavelength range. For example, the total light transmittance may be 82% or more, 84% or more, 85% or more, or 86% or more, and 100% or less, 99% or less, 95% or less, 90% or less, 89% or less, or 88% or less.

According to an embodiment, the polyamide-imide-based film may have a transmittance of 78% or more or 80% or more at a wavelength of 550 nm. For example, the transmittance at a wavelength of 550 nm may be 82% or more, 84% or more, 85% or more, or 86% or more, and 100% or less, 99% or less, 95% or less, 90% or less, 89% or less, or 88% or less.

The polyamide-imide-based film may have a haze of 1% or less. Specifically, the haze may be 0.8% or less, 0.7% or less, 0.6% or less, 0.5% or less, 0.4% or less, 0.3% or less, or 0.25% or less, but it is not limited thereto. The haze of the film may be a value measured in the visible light wavelength range (400 to 700 nm).

The transmittance and haze may be values measured using a haze meter NDH-5000W from Nippon Denshoku Kogyo in Japan in accordance with the JIS K 7105 standard.

The polyamide-imide-based film may have a yellow index of 5 or less. For example, the yellow index may be 4.8 or less, 4.5 or less, 4.3 or less, 4.2 or less, 4.1 or less, or 4.0 or less, but it is not limited thereto.

The yellow index may be a value measured using a spectrophotometer (UltraScan PRO, Hunter Associates Laboratory) under the conditions of d65 and 10° in accordance with the ASTM-E313 standard.

In an embodiment, the polyamide-imide-based film has a thickness deviation of 3 μm or less or 2 μm or less based on a thickness of 50 μm. In addition, the thickness deviation rate may be 5% or less, 4% or less, or 3% or less, but it is not limited thereto.

In an embodiment, the polyamide-imide-based film may have a total light transmittance of 80% or more as measured in the visible light wavelength range, a haze of 1% or less, and a yellow index of 5 or less, based on a film thickness of 50 μm, but it is not limited thereto.

Specifically, the polyamide-imide-based film may have a modulus of 6 GPa or more, a total light transmittance of 85% or more as measured in the visible light wavelength range, a haze of 0.5% or less, and a yellow index of 4.5 or less, based on a film thickness of 50 μm, but it is not limited thereto.

The polyamide-imide-based film may have a compressive strength of 0.4 kgf/μm or more. Specifically, the compressive strength may be 0.45 kgf/μm or more, or 0.46 kgf/μm or more, but it is not limited thereto.

When the polyamide-imide-based film is perforated at a speed of 10 mm/minute using a 2.5-mm spherical tip in a UTM compression mode, the maximum diameter (mm) of perforation including a crack is 60 mm or less. Specifically, the maximum diameter of perforation may be 5 to 60 mm, 10 to 60 mm, 15 to 60 mm, 20 to 60 mm, 25 to 60 mm, or 25 to 58 mm, but it is not limited thereto.

The surface of the polyamide-imide-based film may have a pencil hardness of HB or higher. Specifically, the pencil hardness may be H or higher or 2H or higher, but it is not limited thereto.

The polyamide-imide-based film may have a tensile strength of 15 kgf/mm² or more. Specifically, the tensile strength may be 18 kgf/mm² or more, 20 kgf/mm² or more, 21 kgf/mm² or more, or 22 kgf/mm² or more, but it is not limited thereto.

The polyamide-imide-based film may have an elongation of 15% or more. Specifically, the elongation may be 16% or more, 17% or more, or 18% or more, but it is not limited thereto.

When the polyamide-imide-based film with a thickness of 50 μm is folded to have a radius of curvature of 3 mm, the number of folding before fracture may be 200,000 or more.

The number of folding counts one when the film is folded to have a radius of curvature of 3 mm and then unfolded.

As the number of folding of the polyamide-imide-based film satisfies the above range, it can be advantageously applied to a foldable display device or a flexible display device. Specifically, the film may be applied to foldable phones, but it is not limited thereto.

The polyamide-imide-based film may have a surface roughness of 0.01 μm to 0.07 μm. Specifically, the surface roughness may be 0.01 μm to 0.06 μm, but it is not limited thereto.

As the surface roughness of the polyamide-imide-based film satisfies the above range, it may be advantageous for achieving luminance conditions or a sense of texture preferable for the application thereof to a display device.

The content of residual solvents in the polyamide-imide-based film may be 2,500 ppm or less. For example, the content of residual solvents may be 2,200 ppm or less, 2,000 ppm or less, 1,500 ppm or less, 1,200 ppm or less, 1,000 ppm or less, 800 ppm or less, 500 ppm or less, or 300 ppm or less, but it is not limited thereto.

The residual solvent refers to a solvent that has not been volatilized during the film production and remains in the film finally produced.

If the content of the residual solvents in the polyamide-imide-based film exceeds the above range, the durability of the film may be deteriorated, and it may have an impact on the quality variation of the film. In particular, since it affects the mechanical strength, it may adversely affect the post-processing of the film. Since the hygroscopicity of the film is accelerated, optical properties, let alone mechanical properties, may be deteriorated.

The polyamide-imide-based film according to an embodiment comprises a polyamide-imide-based polymer, which is prepared by polymerizing a diamine compound, a dianhydride compound, and a dicarbonyl compound.

The polyamide-imide-based polymer is a polymer that contains an imide-based repeat unit and an amide-based repeat unit.

Specifically, the polyamide-imide-based polymer comprises an imide-based repeat unit derived from the polymerization of a diamine compound and a dianhydride compound and an amide-based repeat unit derived from the polymerization of a diamine compound and a dicarbonyl compound.

In an embodiment, the polyamide-imide-based polymer may be a polymer of a diamine compound, a dianhydride compound, and a dicarbonyl compound.

The diamine compound is a compound that forms an imide bond with the dianhydride compound and forms an amide bond with the dicarbonyl compound, to thereby form a copolymer.

The diamine compound is not particularly limited, but it may be, for example, an aromatic diamine compound that contains an aromatic structure. For example, the diamine compound may be a compound represented by the following Formula 1.

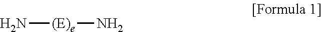

In Formula 1, E may be selected from a substituted or unsubstituted divalent C₆-C₃₀ aliphatic cyclic group, a substituted or unsubstituted divalent C₄-C₃₀ heteroaliphatic cyclic group, a substituted or unsubstituted divalent C₆-C₃₀ aromatic cyclic group, a substituted or unsubstituted divalent C₄-C₃₀ heteroaromatic cyclic group, a substituted or unsubstituted C₁-C₃₀ alkylene group, a substituted or unsubstituted C₂-C₃₀ alkenylene group, a substituted or unsubstituted C₂-C₃₀ alkynylene group, —O—, —S—, —C(═O)—, —CH(OH)—, —S(═O)₂—, —Si(CH₃)₂—, and —C(CH₃)₂—.

e is selected from integers of 1 to 5. When e is 2 or more, the Es may be the same as, or different from, each other.

(E)ₑ in Formula 1 may be selected from the groups represented by the following Formulae 1-1a to 1-14a, but it is not limited thereto.

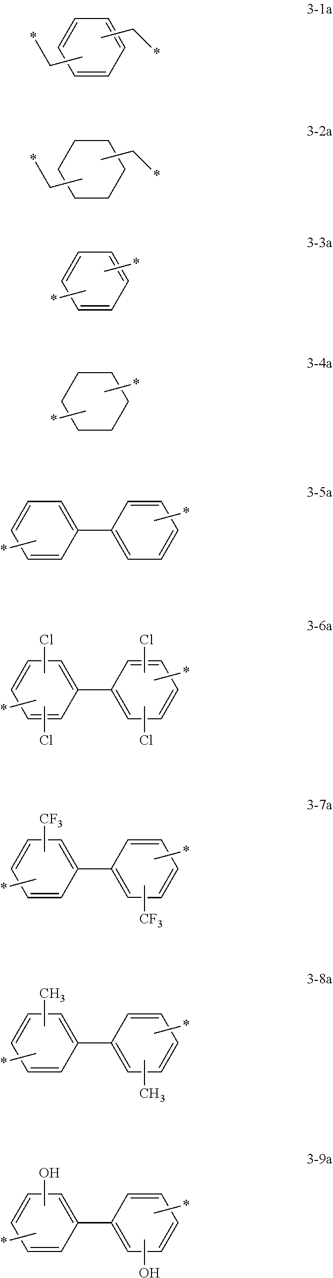

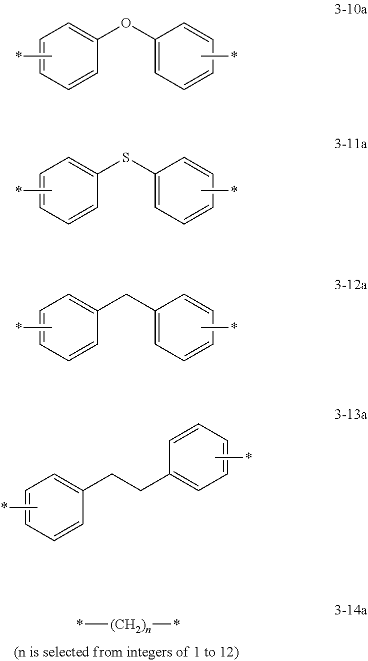

Specifically, (E)ₑ in Formula 1 may be selected from the groups represented by the following Formulae 1-1b to 1-13b, but it is not limited thereto.

Specifically, (E)ₑ in the above Formula 1 may be the group represented by the above Formula 1-7b, but it is not limited thereto.

In an embodiment, the diamine compound may comprise a compound that does not contain a fluorine-containing substituent. The diamine compound may be composed of a compound that does not contain a fluorine-containing substituent.

In another embodiment, the diamine compound may comprise a fluorine-free compound. The diamine compound may be composed of a fluorine-free compound.

In some embodiments, the diamine compound may comprise one kind of diamine compound. That is, the diamine compound may be composed of a single component.

For example, the diamine compound may comprise 2,2′-dimethylbenzidine (m-Tolidine) represented by the following formula, but it is not limited thereto.

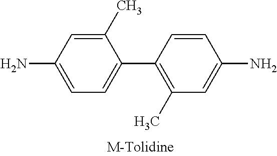 [SMILES: Cc1cc(N)ccc1-c1ccc(N)cc1C]

In an embodiment, the diamine compound may be composed of 2,2′-dimethylbenzidine (m-Tolidine), but it is not limited thereto.

The dianhydride compound has a low birefringence value, so that it can contribute to enhancements in the optical properties such as the transmittance of a film that comprises the polyamide-imide-based polymer.

The dianhydride compound is not particularly limited, but it may be, for example, an aromatic dianhydride compound that contains an aromatic structure. For example, the aromatic dianhydride compound may be a compound represented by the following Formula 2.

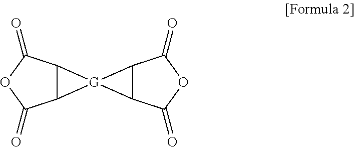

In Formula 2, G may be a group selected from a substituted or unsubstituted tetravalent C₄-C₃₀ aliphatic cyclic group, a substituted or unsubstituted tetravalent C₄-C₃₀ heteroaliphatic cyclic group, a substituted or unsubstituted tetravalent C₆-C₃₀ aromatic cyclic group, or a substituted or unsubstituted tetravalent C₄-C₃₀ heteroaromatic cyclic group, wherein the aliphatic cyclic group, the heteroaliphatic cyclic group, the aromatic cyclic group, or the heteroaromatic cyclic group may be present alone, may be fused to each other to form a condensed ring, or may be bonded by a bonding group selected from a substituted or unsubstituted C₁-C₃₀ alkylene group, a substituted or unsubstituted C₂-C₃₀ alkenylene group, a substituted or unsubstituted C₂-C₃₀ alkynylene group, —O—, —S—, —C(═O)—, —CH(OH)—, —S(═O)₂—, —Si(CH₃)₂—, and —C(CH₃)₂—.

G in the above Formula 2 may be bonded by a substituted or unsubstituted tetravalent C₄-C₃₀ aliphatic cyclic group.

G in the above Formula 2 may be selected from the groups represented by the following Formulae 2-1a to 2-9a, but it is not limited thereto.

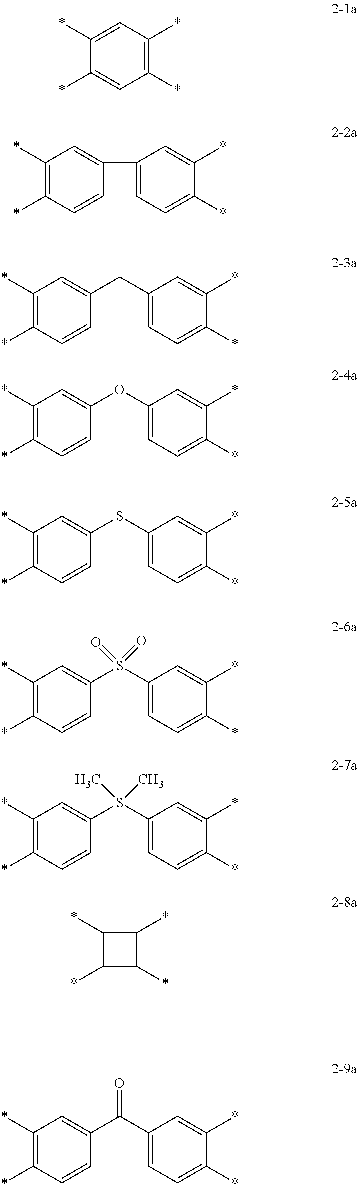

For example, G in Formula 2 may be the group represented by the above Formula 2-2a or the group represented by the above Formula 2-8a.

In an embodiment, the dianhydride compound may comprise a compound that does not contain a fluorine-containing substituent. The dianhydride compound may be composed of a compound that does not contain a fluorine-containing substituent.

In another embodiment, the dianhydride compound may comprise a fluorine-free compound. The dianhydride compound may be composed of a fluorine-free compound.

In another embodiment, the dianhydride compound may be composed of a single component or a mixture of two components.

For example, the dianhydride compound may comprise at least one selected from the group consisting of 1,2,3,4-cyclobutanetetracarboxylic dianhydride (CBDA) and 3,3′,4,4′-biphenyltetracarboxylic dianhydride (BPDA), which have the following structures, but it is not limited thereto.

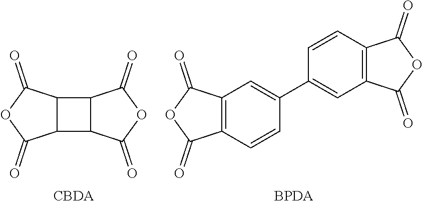

Specifically, the dianhydride compound may comprise 1,2,3,4-cyclobutanetetracarboxylic dianhydride (CBDA).

In an embodiment, the dianhydride compound may be composed of 1,2,3,4-cyclobutanetetracarboxylic dianhydride (CBDA), but it is not limited thereto.

The diamine compound and the dianhydride compound may be polymerized to form a polyamic acid.

Subsequently, the polyamic acid may be converted to a polyimide through a dehydration reaction, and the polyimide comprises an imide repeat unit.

The polyimide may form a repeat unit represented by the following Formula A.

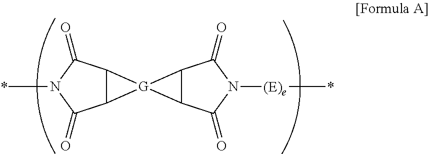

In Formula A, E, G, and e are as described above.

For example, the polyimide may comprise a repeat unit represented by the following Formula A-1, but it is not limited thereto.

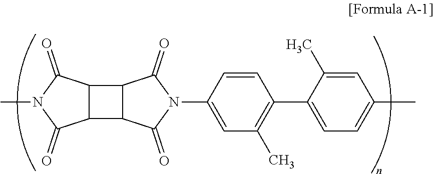

In Formula A-1, n is an integer of 1 to 400.

The dicarbonyl compound is not particularly limited, but it may be, for example, a compound represented by the following Formula 3.

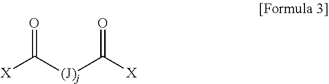

In Formula 3, J may be selected from a substituted or unsubstituted divalent C₆-C₃₀ aliphatic cyclic group, a substituted or unsubstituted divalent C₄-C₃₀ heteroaliphatic cyclic group, a substituted or unsubstituted divalent C₆-C₃₀ aromatic cyclic group, a substituted or unsubstituted divalent C₄-C₃₀ heteroaromatic cyclic group, a substituted or unsubstituted C₁-C₃₀ alkylene group, a substituted or unsubstituted C₂-C₃₀ alkenylene group, a substituted or unsubstituted C₂-C₃₀ alkynylene group, —O—, —S—, —C(═O)—, —CH(OH)—, —S(═O)₂—, —Si(CH₃)₂—, and —C(CH₃)₂—.

j is selected from integers of 1 to 5. When j is 2 or more, the Js may be the same as, or different from, each other.

X is a halogen atom. Specifically, X may be Cl, Br, I, or the like. More specifically, X may be Cl, but it is not limited thereto.

(J)ⱼ in the above Formula 3 may be selected from the groups represented by the following Formulae 3-1a to 3-14a, but it is not limited thereto.

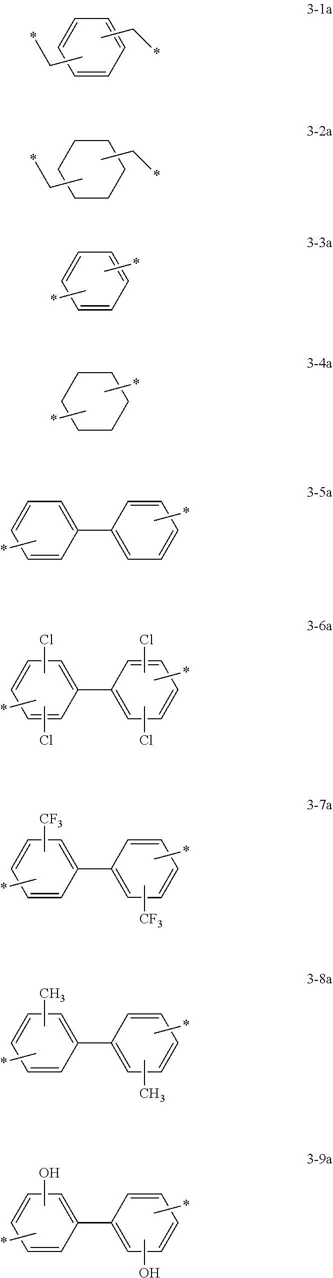

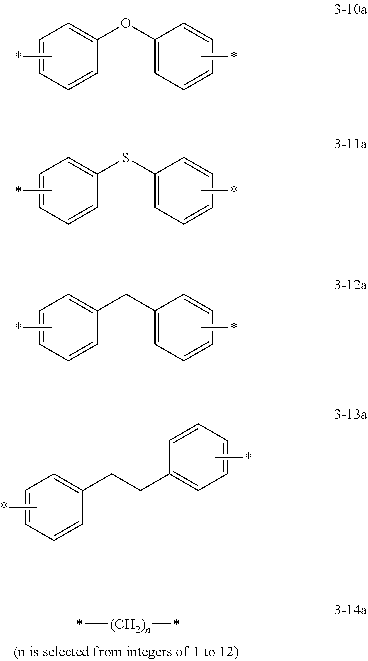

Specifically, (J)ⱼ in the above Formula 3 may be selected from the groups represented by the following Formulae 3-1b to 3-8b, but it is not limited thereto.

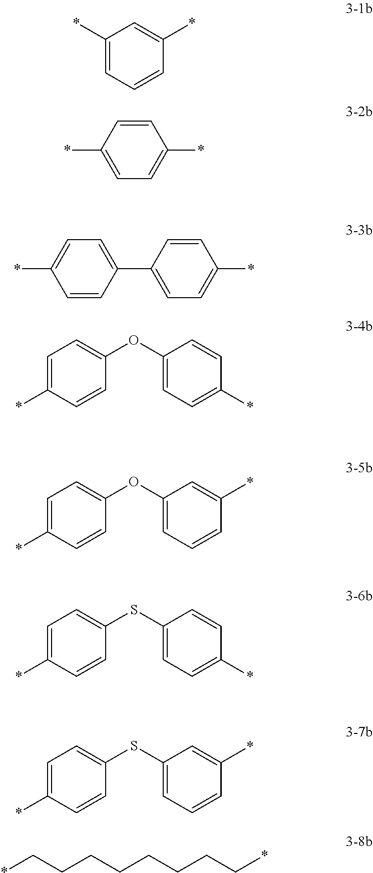

More specifically, (J)ⱼ in Formula 3 may be the group represented by the above Formula 3-1b, the group represented by the above Formula 3-2b, the group represented by the above Formula 3-3b, or the group represented by the above Formula 3-8b.

For example, (J)ⱼ in the above Formula 3 may be the group represented by the above Formula 3-1b or the group represented by the above Formula 3-2b.

In an embodiment, one kind of a dicarbonyl compound may be used alone, or a mixture of at least two kinds of dicarbonyl compounds different from each other may be used, as the dicarbonyl compound. If two or more dicarbonyl compounds are used, at least two dicarbonyl compounds in which (J)ⱼ in the above Formula 3 is selected from the groups represented by the above Formulae 3-1b to 3-8b may be used as the dicarbonyl compound.

In another embodiment, the dicarbonyl compound may be an aromatic dicarbonyl compound that contains an aromatic structure.

In an embodiment, the dicarbonyl compound may comprise a fluorine-free compound. The dicarbonyl compound may be composed of a fluorine-free compound. The dicarbonyl compound may comprise terephthaloyl chloride (TPC), 1,1′-biphenyl-4,4′-dicarbonyl dichloride (BPDC), isophthaloyl chloride (IPC), as represented by the following formulae, or a combination thereof. But it is not limited thereto.

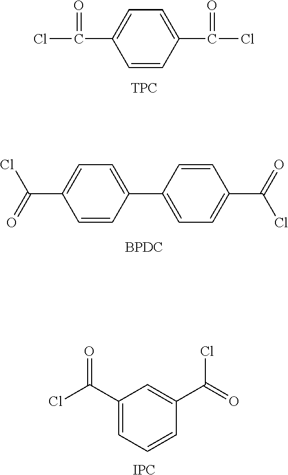

In an embodiment, the dicarbonyl compound may be composed of terephthaloyl chloride (TPC) and isophthaloyl chloride (IPC), but it is not limited thereto.

The diamine compound and the dicarbonyl compound may be polymerized to form a repeat unit represented by the following Formula B.

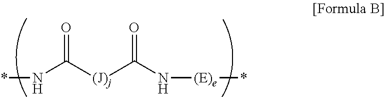

In Formula B, E, J, e, and j are as described above.

For example, the diamine compound and the dicarbonyl compound may be polymerized to form amide repeat units represented by the following Formulae B-1, B-2, or B-3.

Alternatively, the diamine compound and the dicarbonyl compound may be polymerized to form amide repeat units represented by the following Formulae B-2 or B-3.

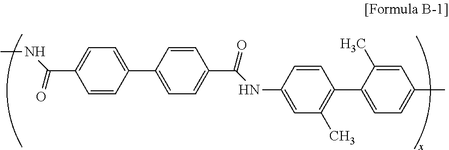

In Formula B-1, x is an integer of 1 to 400.

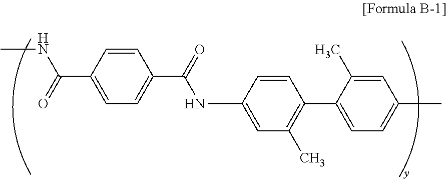

In Formula B-2, y is an integer of 1 to 400.

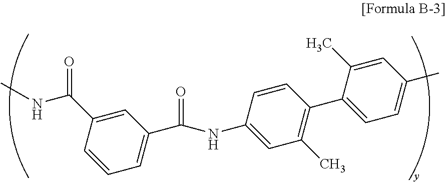

In Formula B-3, y is an integer of 1 to 400.

According to an embodiment, the polyamide-imide-based polymer is a polymer of a diamine compound, a dianhydride compound, and a dicarbonyl compound. The diamine compound may be represented by the above Formula 1, the dianhydride compound may be represented by the above Formula 2, and the dicarbonyl compound may be represented by the above Formula 3.

According to an embodiment, the polyamide-imide-based polymer may comprise a repeat unit represented by the following Formula A and a repeat unit represented by the following Formula B:

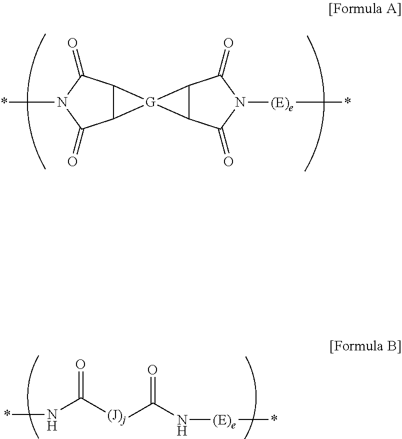

In Formulae A and B, E and J are each independently selected from a substituted or unsubstituted divalent C₆-C₃₀ aliphatic cyclic group, a substituted or unsubstituted divalent C₄-C₃₀ heteroaliphatic cyclic group, a substituted or unsubstituted divalent C₆-C₃₀ aromatic cyclic group, a substituted or unsubstituted divalent C₄-C₃₀ heteroaromatic cyclic group, a substituted or unsubstituted C₁-C₃₀ alkylene group, a substituted or unsubstituted C₂-C₃₀ alkenylene group, a substituted or unsubstituted C₂-C₃₀ alkynylene group, —O—, —S—, —C(═O)—, —CH(OH)—, —S(═O)₂—, —Si(CH₃)₂—, and —C(CH₃)₂—.

e and j are each independently selected from integers of 1 to 5,
when e is 2 or more, then the two or more Es are the same as, or different from, each other,
when j is 2 or more, then the two or more Js are the same as, or different from, each other,
G may be a group selected from a substituted or unsubstituted tetravalent C₄-C₃₀ aliphatic cyclic group, a substituted or unsubstituted tetravalent C₄-C₃₀ heteroaliphatic cyclic group, a substituted or unsubstituted tetravalent C₆-C₃₀ aromatic cyclic group, or a substituted or unsubstituted tetravalent C₄-C₃₀ heteroaromatic cyclic group, wherein the aliphatic cyclic group, the heteroaliphatic cyclic group, the aromatic cyclic group, or the heteroaromatic cyclic group may be present alone, may be fused to each other to form a condensed ring, or may be bonded by a bonding group selected from a substituted or unsubstituted C₁-C₃₀ alkylene group, a substituted or unsubstituted C₂-C₃₀ alkenylene group, a substituted or unsubstituted C₂-C₃₀ alkynylene group, —O—, —S—, —C(═O)—, —CH(OH)—, —S(═O)₂—, —Si(CH₃)₂—, and —C(CH₃)₂—.

In an embodiment, the diamine compound, the dianhydride compound, and the dicarbonyl compound may each be free of fluorine atoms.

The polyamide-imide-based polymer may comprise an imide-based repeat unit and an amide-based repeat unit at a molar ratio of 2:98 to 70:30. Specifically, the molar ratio of an imide-based repeat unit to an amide-based repeat unit may be 2:98 to 60:40, 2:98 to 55:45, 2:98 to 50:50, 2:98 to 45:55, 2:98 to 40:60, 2:98 to 35:65, 2:98 to 30:70, 3:97 to 70:30, 3:97 to 60:40, 3:97 to 55:45, 3:97 to 50:50, 3:97 to 45:55, 3:97 to 40:60, 3:97 to 30:70, 5:95 to 70:30, 5:95 to 60:40, 5:95 to 55:45, 5:95 to 50:50, 5:95 to 40:60, 5:95 to 30:70, or 10:90 to 40:60, but it is not limited thereto.

When the molar ratio of an imide-based repeat unit to an amide-based repeat unit is within the above range, the quality reliability of a film can be enhanced in association with a characteristic processing method, and excellent optical properties, mechanical properties, and UV blocking rates can be achieved.

In the polyamide-imide-based polymer, the molar ratio of the repeat unit represented by the above Formula A to the repeat unit represented by the above Formula B may be 2:98 to 70:30. Specifically, the molar ratio of the repeat unit represented by Formula A to the repeat unit represented by Formula B may be 2:98 to 60:40, 2:98 to 55:45, 2:98 to 50:50, 2:98 to 40:60, 2:98 to 30:70, 3:97 to 70:30, 3:97 to 60:40, 3:97 to 55:45, 3:97 to 50:50, 3:97 to 40:60, 3:97 to 30:70, 5:95 to 70:30, 5:95 to 60:40, 5:95 to 55:45, 5:95 to 50:50, 5:95 to 40:60, 5:95 to 30:70, or 10:90 to 40:60, but it is not limited thereto.

In an embodiment, the polyamide-imide-based polymer may comprise one or more types of an amide-based repeat unit. Specifically, the polyamide-imide-based polymer may comprise two or more types of an amide-based repeat unit.

In an embodiment, the polyamide-imide-based polymer may comprise a first amide-based repeat unit and a second amide-based repeat unit. The first amide-based repeat unit may be formed by a reaction between a first dicarbonyl compound and the diamine compound, and the second amide-based repeat unit may be formed by a reaction between a second dicarbonyl compound and the diamine compound.

As another example, the polyamide-imide-based polymer may comprise a first amide-based repeat unit derived from a first dicarbonyl compound and a second amide-based repeat unit derived from a second dicarbonyl compound. Specifically, the first amide-based repeat unit may be derived from a first dicarbonyl compound, and the second amide-based repeat unit may be derived from a second dicarbonyl compound.

The first dicarbonyl compound and the second dicarbonyl compound may be compounds different from each other.

The first dicarbonyl compound and the second dicarbonyl compound may comprise two carbonyl groups, respectively. The angle between the two carbonyl groups contained in the first dicarbonyl compound may be greater than the angle between the two carbonyl groups contained in the second dicarbonyl compound.

In some embodiments, the first dicarbonyl compound and the second dicarbonyl compound may be structural isomers to each other.

The first dicarbonyl compound and the second dicarbonyl compound may be an aromatic dicarbonyl compound, respectively. In some embodiments, the first dicarbonyl compound and the second dicarbonyl compound may each have one benzene ring (a phenyl group).

For example, the first dicarbonyl compound and the second dicarbonyl compound may be aromatic dicarbonyl compounds different from each other, but they are not limited thereto.

When the first dicarbonyl compound and the second dicarbonyl compound are an aromatic dicarbonyl compound, respectively, they comprise a benzene ring. Thus, they can contribute to improvements in the mechanical properties, such as pencil hardness and tensile strength, of a film that comprises the polyamide-imide-based polymer thus produced.

For example, the angle between the two carbonyl groups contained in the first dicarbonyl compound may be 160 to 180°, and the angle between the two carbonyl groups contained in the second dicarbonyl compound may be 80 to 140°.

For example, the first dicarbonyl compound may comprise TPC, and the second dicarbonyl compound may comprise IPC, but they are not limited thereto.

When TPC is used as the first dicarbonyl compound and IPC is used as the second dicarbonyl compound in a proper combination, it contributes to increasing the viscosity of a film during polymerization, so that the film forming process can be appropriately carried out. A film comprising the polyamide-imide-based polymer thus prepared can have high light transmittance, modulus, along with a low haze and yellow index, and improved ultraviolet ray blocking rates.

In an embodiment, the polyamide-imide-based polymer comprises an imide-based repeat unit, a first amide-based repeat unit, and a second amide-based repeat unit. When the sum of the imide-based repeat unit, the first amide-based repeat unit, and the second amide-based repeat unit is 100% by mole, the molar ratio of the first amide-based repeat unit may be 70% by mole or less. Specifically, when the sum of the imide-based repeat unit, the first amide-based repeat unit, and the second amide-based repeat unit is 100% by mole, the molar ratio of the first amide-based repeat unit may be 65% by mole or less, 60% by mole or less, 58% by mole or less, 55% by mole or less, 50% by mole or less, or 40% by mole or less, but it is not limited thereto.

The molar ratio of the first amide-based repeat unit to the second amide-based repeat unit may be 21:79 to 79:21. Specifically, the molar ratio of the first amide-based repeat unit to the second amide-based repeat unit may be 25:75 to 79:21, 30:70 to 79:21, 35:65 to 79:21, 40:60 to 79:21, 21:79 to 75:25, 25:75 to 75:25, 30:70 to 75:25, 35:65 to 75:25, or 40:60 to 75:25.

As the molar ratio of the first and second amide-based repeat units is set to the above range, the physical properties of a polyamide-imide-based film can be controlled to a desired range.

The polyamide-imide-based film according to an embodiment may further comprise at least one selected from the group consisting of a filler, a blue pigment, and a UVA absorber in addition to the polyamide-imide-based polymer.

The filler may comprise, for example, an oxide, a carbonate, or a sulfate of a metal or metalloid. For example, the filler may comprise silica, calcium carbonate, barium sulfate, or the like, but it is not limited thereto.

The filler may be employed in the form of particles. In addition, the surface of the filler is not subjected to special coating treatment, and it may be uniformly dispersed in the entire film.

As the polyamide-imide-based film comprises the filler, it is possible to secure a wide angle of view without a deterioration in the optical properties of the film and to enhance not only the roughness and winderability but also the effect of improving the scratches caused by sliding in the preparation of the film.

The filler may have a refractive index of 1.55 to 1.75. Specifically, the refractive index of the filler may be 1.60 to 1.75, 1.60 to 1.70, 1.60 to 1.68, or 1.62 to 1.65, but it is not limited thereto.

When the refractive index of the filler satisfies the above range, the birefringence values related to the x-direction refractive index (nx), y-direction refractive index (ny), and z-direction refractive index (nz) can be appropriately adjusted, and the luminance of the film at various angles can be improved.

On the other hand, if the refractive index of the filler is outside the above range, there may arise a problem in that the filler is visually noticeable on the film or that the haze is increased due to the filler.

The content of the filler may be 100 ppm to 15,000 ppm based on the total weight of the solids content of the polyamide-imide-based polymer. Specifically, the content of the filler may be 100 ppm to 14,500 ppm, 100 ppm to 14,200 ppm, 200 ppm to 14,500 ppm, 200 ppm to 14,200 ppm, 250 ppm to 14,100 ppm, or 300 ppm to 14,000 ppm, based on the total weight of the solids content of the polyamide-imide-based polymer, but it is not limited thereto.

If the content of the filler is outside the above range, the haze of the film is steeply increased, and the filler may aggregate with each other on the surface of the film, so that a feeling of foreign matter may be visually observed, or it may cause a trouble in the sliding performance or deteriorate the windability in the preparation process.

In some embodiments, the blue pigment may be employed in an amount of 50 to 5,000 ppm based on the total weight of the polyamide-imide-based polymer. Preferably, the blue pigment may be employed in an amount of 100 to 5,000 ppm, 200 to 5,000 ppm, 300 to 5,000 ppm, 400 to 5,000 ppm, 50 to 3,000 ppm, 100 to 3,000 ppm, 200 to 3,000 ppm, 300 to 3,000 ppm, 400 to 3,000 ppm, 50 to 2,000 ppm, 100 to 2,000 ppm, 200 to 2,000 ppm, 300 to 2,000 ppm, 400 to 2,000 ppm, 50 to 1,000 ppm, 100 to 1,000 ppm, 200 to 1,000 ppm, 300 to 1,000 ppm, or 400 to 1,000 ppm, based on the total weight of the polyamide-imide-based polymer, but it is not limited thereto.

The UVA absorber may comprise an absorber that absorbs electromagnetic waves of a wavelength of 10 to 400 nm used in the art. For example, the UVA absorber may comprise a benzotriazole-based compound. The benzotriazole-based compound may comprise an N-phenolic benzotriazole-based compound. In some embodiments, the N-phenolic benzotriazole-based compound may comprise N-phenolic benzotriazole in which the phenol group is substituted with an alkyl group having 1 to 10 carbon atoms. It may be substituted with two or more of the alkyl group, which may be linear, branched, or cyclic.

In some embodiments, the UVA absorber may be employed in an amount of 0.1 to 10% by weight based on the total weight of the polyamide-imide-based polymer. Preferably, the UVA absorber may be employed in an amount of 0.1 to 5% by weight, 0.1 to 3% by weight, 0.1 to 2% by weight, 0.5 to 10% by weight, 0.5 to 5% by weight, 0.5 to 3% by weight, 0.5 to 2% by weight, 1 to 10% by weight, 1 to 5% by weight, 1 to 3% by weight, or 1 to 2% by weight, relative to the total weight of the polyamide-imide-based polymer, but it is not limited thereto.

The physical properties of the polyamide-imide-based film as described above are based on a thickness of 20 μm to 80 μm. For example, the physical properties of the polyamide-imide-based film are based on a thickness of 50 μm.

The polyamide-imide-based film may have a thickness of 20 μm to 100 μm. Specifically, the thickness of the polyamide-imide-based film may be 20 μm to 80 μm, 20 μm to 60 μm, 20 μm to 50 μm, 25 μm to 100 μm, 25 μm to 80 μm, 25 μm to 60 μm, or 25 μm to 50 μm, but it is not limited thereto.

The thickness of the film may be determined by measuring the thickness at five random points of the film and taking the average value. Specifically, the thickness of the film may be measured at 5 random points using a digital micrometer 547-401 from Mitutoyo Corporation, and their average value is taken as the thickness.

The features on the components and properties of the polyamide-imide-based film as described above may be combined with each other.

In addition, the presence or absence and content of fluorine atoms in the polyamide-imide-based film and/or the polyamide-imide-based polymer can be controlled not only by the types of monomers used in the polymerization process, but also by the additives used in the polymerization process and the additives used in the post-processing.

Further, the modulus, transmittance, haze, and the like of the polyamide-imide-based film may be adjusted by combinations of the chemical and physical properties of the components, which constitute the polyamide-imide-based film, along with the specific conditions in each step of the process for preparing the polyamide-imide-based film as described below.

For example, various factors such as the compositions and contents of the components that constitute the polyamide-imide-based film, the residual content of solvents, the polymerization conditions and thermal treatment conditions in the thermal treatment and cooling steps in the film preparation process, and the like are all combined to achieve the physical properties of the film in the desired ranges.

### Cover Window for a Display Device

The cover window for a display device according to an embodiment comprises a polyamide-imide-based film and a functional layer.

The polyamide-imide-based film comprises a polyamide-imide-based polymer that is free of fluorine atoms, wherein the polyamide-imide-based film has a modulus of 5 GPa or more based on a film thickness of 50 μm.

Details on the polyamide-imide-based film are as described above.

The cover window for a display device can be advantageously applied to a display device.

### Display Device

The display device according to an embodiment comprises a display unit; and a cover window disposed on the display unit, wherein the cover window comprises a polyamide-imide-based film and a functional layer.

The polyamide-imide-based film comprises a polyamide-imide-based polymer that is free of fluorine atoms, wherein the polyamide-imide-based film has a modulus of 5 GPa or more based on a film thickness of 50 μm.

Details on the polyamide-imide-based film and the cover window are as described above.

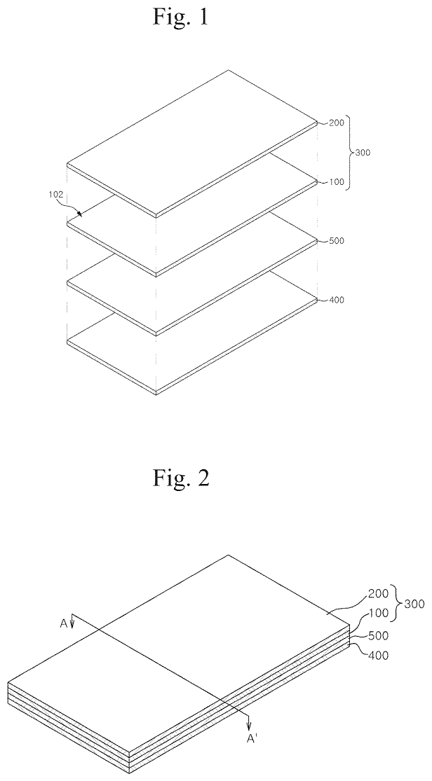

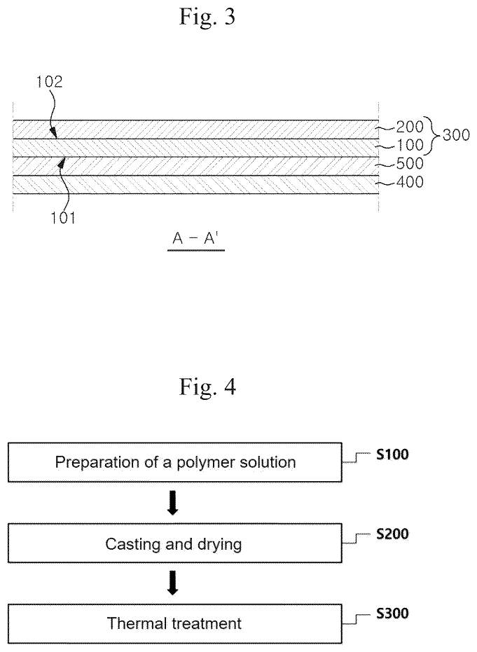

FIG. 1 is a schematic exploded view of a display device according to an embodiment. FIG. 2 is a schematic perspective view of a display device according to an embodiment. FIG. 3 is a schematic cross-sectional view of a display device according to an embodiment.

Specifically, FIGS. 1 to 3 each illustrate a display device, which comprises a display unit (400) and a cover window (300) disposed on the display unit (400), wherein the cover window comprises a polyamide-imide-based film (100) having a first side (101) and a second side (102) and a functional layer (200), and an adhesive layer (500) is interposed between the display unit (400) and the cover window (300).

The display unit (400) is for displaying an image, and it may have flexible characteristics.

The display unit (400) may be a display panel for displaying an image. For example, it may be a liquid crystal display panel or an organic electroluminescent display panel. The organic electroluminescent display panel may comprise a front polarizing plate and an organic EL panel.

The front polarizing plate may be disposed on the front side of the organic EL panel. Specifically, the front polarizing plate may be attached to the side on which an image is displayed in the organic EL panel.

The organic EL panel may display an image by self-emission of a pixel unit. The organic EL panel may comprise an organic EL substrate and a driving substrate.

The organic EL substrate may comprise a plurality of organic electroluminescent units, each of which corresponds to a pixel. Specifically, it may comprise a cathode, an electron transport layer, a light-emitting layer, a hole transport layer, and an anode. The driving substrate is operatively coupled to the organic EL substrate. That is, the driving substrate may be coupled to the organic EL substrate so as to apply a driving signal such as a driving current, so that the driving substrate can drive the organic EL substrate by applying a current to the respective organic electroluminescent units.

In addition, an adhesive layer (500) may be interposed between the display unit (400) and the cover window (300). The adhesive layer may be an optically transparent adhesive layer, but it is not particularly limited.

The cover window (300) may be disposed on the display unit (400). The cover window is located at the outer position of the display device to thereby protect the display unit.

The cover window (300) may comprise a polyamide-imide-based film and a functional layer. The functional layer may be at least one selected from the group consisting of a hard coating layer, a reflectance reducing layer, an antifouling layer, and an antiglare layer. The functional layer may be coated on at least one side of the polyamide-imide-based film.

The polyamide-imide-based film according to an embodiment can be applied in the form of a film to the outside of a display device without changing the display driving method, the color filter inside the panel, or the laminated structure, thereby providing a display device having a uniform thickness, low haze, high transmittance, and high transparency. Since neither significant process changes nor cost increases are needed, it is advantageous in that the production costs can be reduced.

The polyamide-imide-based film according to an embodiment may be excellent in optical properties in terms of high transmittance, low haze, and low yellow index, as well as may have excellent mechanical properties such as modulus and flexibility, and the change (deterioration) of its optical and mechanical properties can be suppressed when it is exposed to ultraviolet rays.

Specifically, the polyamide-imide-based film according to an embodiment can have excellent optical properties, mechanical properties, and ultraviolet ray blocking rates. As a result, when the polyamide-imide-based film is applied to a cover window for a display device or to a display device, the quality reliability and product yield of a final product can be enhanced.

### Process for Preparing a Polyamide-Imide-Based Film

An embodiment provides a process for preparing a polyamide-imide-based film.

The process for preparing a polyamide-imide-based film according to an embodiment comprises polymerizing a diamine compound, a dianhydride compound, and a dicarbonyl compound in an organic solvent to prepare a polyamide-imide-based polymer solution (S100); casting the solution and then drying it to prepare a gel sheet (S200); and thermally treating the gel sheet (S300) (see FIG. 4).

The process for preparing a polyamide-imide-based film according to some embodiments may further comprise adjusting the viscosity of the polyamide-imide-based polymer solution (S110), aging the polyamide-imide-based polymer solution (S120), and/or degassing the polyamide-imide-based polymer solution (S130).

The polyamide-imide-based film is a film in which a polyamide-imide-based polymer is a main component. The polyamide-imide-based polymer is a resin that comprises an imide repeat unit and an amide repeat unit at a predetermined molar ratio as a structural unit.

In the process for preparing a polyamide-imide-based film, a polymer solution for preparing the polyamide-imide-based polymer may be prepared by simultaneously or sequentially mixing a diamine compound, a dianhydride compound, and a dicarbonyl compound in an organic solvent in a reactor, and reacting the mixture (S100).

In an embodiment, the polymer solution may be prepared by simultaneously mixing and reacting a diamine compound, a dianhydride compound, and a dicarbonyl compound in an organic solvent.

In another embodiment, the step of preparing the polymer solution may comprise first mixing and reacting the diamine compound and the dianhydride compound in a solvent to produce a polyamic acid (PAA) solution; and second mixing and reacting the polyamic acid (PAA) solution and the dicarbonyl compound to form an amide bond and an imide bond. The polyamic acid solution is a solution that comprises a polymer containing an amic acid repeat unit.

Alternatively, the step of preparing the polymer solution may comprise first mixing and reacting the diamine compound and the dianhydride compound in a solvent to produce a polyamic acid solution; subjecting the polyamic acid solution to dehydration to produce a polyimide (PI) solution; and second mixing and reacting the polyimide (PI) solution and the dicarbonyl compound to further form an amide bond. The polyimide solution is a solution that comprises a polymer having an imide repeat unit.

In still another embodiment, the step of preparing the polymer solution may comprise first mixing and reacting the diamine compound and the dicarbonyl compound in a solvent to produce a polyamide (PA) solution; and second mixing and reacting the polyamide (PA) solution and the dianhydride compound to further form an imide bond. The polyamide solution is a solution that comprises a polymer having an amide repeat unit.

The polymer solution thus prepared may be a solution that comprises a polymer containing at least one selected from the group consisting of a polyamic acid (PAA) repeat unit, a polyamide (PA) repeat unit, and a polyimide (PI) repeat unit.

Alternatively, the polymer contained in the polymer solution comprises an imide repeat unit derived from the polymerization of the diamine compound and the dianhydride compound and an amide repeat unit derived from the polymerization of the diamine compound and the dicarbonyl compound.

Details on the diamine compound, the dianhydride compound, and the dicarbonyl compound are as described above.

The content of solids contained in the polymer solution may be 10% by weight to 30% by weight. Alternatively, the content of solids contained in the polymer solution may be 15% by weight to 25% by weight, but it is not limited thereto.

When the content of solids contained in the polymer solution is within the above range, a polyamide-imide-based film can be effectively produced in the extrusion and casting steps. In addition, the polyamide-imide-based film thus produced may have excellent optical properties and ultraviolet ray blocking rates.

In another embodiment, the step of preparing the polymer solution may further comprise introducing a catalyst.

Here, the catalyst may comprise at least one selected from the group consisting of beta picoline, acetic anhydride, isoquinoline (IQ), and pyridine-based compounds, but it is not limited thereto.

The catalyst may be added in an amount of 0.01 to 0.5 molar equivalent, 0.01 to 0.4 molar equivalent, or 0.01 to 0.3 molar equivalent, based on 1 mole of the polyamic acid, but it is not limited thereto.

The further addition of the catalyst may expedite the reaction rate and enhance the chemical bonding force between the repeat unit structures or that within the repeat unit structures.

In an embodiment, the step of preparing the polymer solution may further comprise adjusting the viscosity of the polymer solution (S110). The viscosity of the polymer solution may be 80,000 cps to 500,000 cps, 100,000 cps to 500,000 cps, 150,000 cps to 500,000 cps, 150,000 cps to 450,000 cps, 200,000 cps to 450,000 cps, 200,000 cps to 400,000 cps, 200,000 cps to 350,000 cps, or 250,000 cps to 350,000 cps at room temperature. In such an event, the film-forming capability of a polyamide-imide-based film can be enhanced, thereby enhancing the thickness uniformity.

Specifically, the step of preparing the polymer solution may comprise simultaneously or sequentially mixing and reacting a diamine compound, a dianhydride compound, and a dicarbonyl compound in an organic solvent to prepare a first polymer solution; and further adding the dicarbonyl compound to prepare a second polymer solution having the target viscosity.

In the steps of preparing the first polymer solution and the second polymer solution, the polymer solutions have viscosities different from each other. For example, the second polymer solution has a viscosity higher than that of the first polymer solution.

Specifically, the viscosity of the polymer solution may be measured using BH-II equipment of TOKI SANGYO under constant temperature conditions at 25° C. with RPM set to 4 and spindle number 4.

In the steps of preparing the first polymer solution and the second polymer solution, the stirring speeds may be different from each other. For example, the stirring speed when the first polymer solution is prepared may be faster than the stirring speed when the second polymer solution is prepared.

In still another embodiment, the step of preparing the polymer solution may further comprise adjusting the pH of the polymer solution. In this step, the pH of the polymer solution may be adjusted to 4 to 7, for example, 4.5 to 7.

The pH of the polymer solution may be adjusted by adding a pH adjusting agent. The pH adjusting agent is not particularly limited and may include, for example, amine-based compounds such as alkoxyamine, alkylamine, and alkanolamine.

As the pH of the polymer solution is adjusted to the above range, it is possible to prevent the occurrence of defects in a film produced from the polymer solution and to achieve the desired optical properties and mechanical properties in terms of yellow index and modulus.

The pH adjusting agent may be employed in an amount of 0.1% by mole to 10% by mole based on the total number of moles of monomers in the polymer solution.

In an embodiment, the organic solvent may be at least one selected from the group consisting of dimethylformamide (DMF), dimethylacetamide (DMAc), N-methyl-2-pyrrolidone (NMP), m-cresol, tetrahydrofuran (THF), and chloroform. The organic solvent employed in the polymer solution may be dimethylacetamide (DMAc), but it is not limited thereto.

In another embodiment, at least one selected from the group consisting of a filler, a blue pigment, and a UVA absorber may be added to the polymer solution.

Details on the types and contents of the filler, blue pigment, and UVA absorber are as described above. The filler, blue pigment, and UVA absorber may be mixed with the polyamide-imide-based polymer in the polymer solution.

The polymer solution may be stored at −20° C. to 20° C., −20° C. to 10° C., −20° C. to 5° C., −20° C. to 0° C., or 0° C. to 10° C.

When it is stored at the above temperature, it is possible to prevent degradation of the polymer solution and to lower the moisture content to thereby prevent defects of a film produced therefrom.

In some embodiments, the polymer solution or the polymer solution whose viscosity has been adjusted may be aged (S120).

The aging may be carried out by leaving the polymer solution at a temperature of −10 to 10° C. for 24 hours or longer. In such an event, the polyamide-imide-based polymer or unreacted materials contained in the polymer solution, for example, may complete the reaction or achieve chemical equilibrium, whereby the polymer solution may be homogenized. The mechanical properties and optical properties of a polyamide-imide-based film formed therefrom may be substantially uniform over the entire area of the film. Preferably, the aging may be carried out at a temperature of −5 to 10° C., −5 to 5° C., or −3 to 5° C., but it is not limited thereto.

In an embodiment, the process may further comprise degassing the polyamide-imide-based polymer solution (S130). The step of degassing may remove moisture in the polymer solution and reduce impurities, thereby increasing the reaction yield and imparting excellent surface appearance and mechanical properties to the film finally produced.

The degassing may comprise vacuum degassing or purging with an inert gas.

The vacuum degassing may be carried out for 30 minutes to 3 hours after depressurizing the internal pressure of a tank in which the polymer solution is contained to 0.1 bar to 0.7 bar. The vacuum degassing under these conditions may reduce bubbles in the polymer solution. As a result, it is possible to prevent surface defects of a film produced therefrom and to achieve excellent optical properties such as haze.

In addition, the purging may be carried out by purging the tank with an inert gas at an internal pressure of 1 atm to 2 atm. The purging under these conditions may remove moisture in the polymer solution, reduce impurities to thereby increase the reaction yield, and achieve excellent optical properties such as haze and mechanical properties.

The inert gas may be at least one selected from the group consisting of nitrogen, helium (He), neon (Ne), argon (Ar), krypton (Kr), xenon (Xe), and radon (Rn), but it is not limited thereto. Specifically, the inert gas may be nitrogen.

The vacuum degassing and the purging with an inert gas may be carried out in separate steps.

For example, the step of vacuum degassing may be carried out, followed by the step of purging with an inert gas, but it is not limited thereto.

The vacuum degassing and/or the purging with an inert gas may improve the physical properties of the surface of a polyamide-imide-based film thus produced.

The polymer solution may be cast to prepare a gel sheet (S200).

For example, the polymer solution may be extruded, coated, and/or dried on a support to form a gel sheet.

In addition, the casting thickness of the polymer solution may be 200 μm to 700 μm. As the polymer solution is cast to a thickness within the above range, the final film produced after the drying and thermal treatment may have an appropriate and uniform thickness.

The polymer solution may have a viscosity of 100,000 cps to 500,000 cps or 150,000 cps to 500,000 cps at room temperature as described above. As the viscosity satisfies the above range, the polymer solution can be cast to a uniform thickness without defects, and a polyamide-imide-based film having a substantially uniform thickness can be formed without local/partial thickness variations during drying.

The polymer solution is cast and then dried at a temperature of 60° C. to 150° C., 70° C. to 150° C., 80° C. to 150° C., or 90° C. to 150° C., for 5 minutes to 60 minutes to prepare a gel sheet. Specifically, the polymer solution is dried at a temperature of 90° C. to 140° C. for 15 minutes to 40 minutes to prepare a gel sheet.

The solvent of the polymer solution may be partially or totally volatilized during the drying to prepare the gel sheet.

The dried gel sheet may be thermally treated to form a polyamide-imide-based film (S300).

The thermal treatment of the gel sheet may be carried out, for example, through a thermosetting device.

The step of thermally treating the gel sheet comprises thermal treatment through at least one heater.

In addition, the step of thermally treating the gel sheet may further comprise thermal treatment with hot air.

In an embodiment, the step of thermally treating the gel sheet may comprise thermal treatment with hot air; and thermal treatment through at least one heater.

In an embodiment, when the thermal treatment with hot air is carried out, heat may be uniformly supplied. If heat is not uniformly supplied, a satisfactory surface roughness cannot be achieved, or the surface quality may not be uniform, and the surface energy may be raised or lowered too much.

The thermal treatment with hot air may be carried out in a temperature range of 60° C. to 500° C. for 5 minutes to 200 minutes. Specifically, the thermal treatment of the gel sheet may be carried out in a temperature range of 80° C. to 300° C. at a temperature elevation rate of 1.5° C./minute to 20° C./minute for 10 minutes to 150 minutes. More specifically, the thermal treatment of the gel sheet may be carried out in a temperature range of 140° C. to 250° C.

In such an event, the initial temperature of the thermal treatment of the gel sheet by hot air may be 60° C. or higher. Specifically, the initial temperature of the thermal treatment of the gel sheet may be 80° C. to 180° C. In addition, the maximum temperature in the thermal treatment may be 200° C. to 500° C.

In addition, the thermal treatment of the gel sheet may be carried out in two or more stages. Specifically, the thermal treatment of the gel sheet with hot air may be carried out sequentially in a first hot air treatment stage and a second hot air treatment stage. The temperature in the second hot air treatment stage may be higher than the temperature in the first hot air treatment stage.

In an embodiment, the step of thermally treating the gel sheet may comprise second thermal treatment through at least one heater, specifically, thermal treatment through a plurality of heaters.

The plurality of heaters may comprise a plurality of heaters spaced apart from each other in the transverse direction (TD direction) of the gel sheet. The plurality of heaters may be mounted on a heater mounting part, and two or more heater mounting parts may be disposed along the moving direction (MD direction) of the gel sheet.

The at least one heater may comprise an IR heater. However, the type of the at least one heater is not limited to the above example and may be variously modified. Specifically, the plurality of heaters may each comprise an IR heater.

The thermal treatment by the at least one heater may be carried out in a temperature range of 250° C. or higher. Specifically, the thermal treatment by the at least one heater may be carried out for 1 minute to 30 minutes or 1 minute to 20 minutes in a temperature range of 250° C. to 400° C.

In the thermal treatment with a heater, the temperature stated above is the temperature in the thermal treatment device in which the gel sheet is present. It corresponds to a temperature measured by a temperature sensor located in the second thermal treatment section of the thermal treatment device.

Subsequently, after the step of thermal treatment of the gel sheet, a step of cooling the cured film may be carried out while it is transferred.

The step of cooling the cured film while it is transferred may comprise a first temperature lowering step of lowering the temperature at a rate of 100° C./minute to 1,000° C./minute and a second temperature lowering step of lowering the temperature at a rate of 40° C./minute to 400° C./minute.

In such an event, specifically, the second temperature lowering step is performed after the first temperature lowering step. The temperature lowering rate of the first temperature lowering step may be faster than the temperature lowering rate of the second temperature lowering step.

For example, the maximum rate of the first temperature lowering step is faster than the maximum rate of the second temperature lowering step. Alternatively, the minimum rate of the first temperature lowering step is faster than the minimum rate of the second temperature lowering step.

If the step of cooling the cured film is carried out in such a multistage manner, it is possible to have the physical properties of the cured film further stabilized and to maintain the optical properties and mechanical properties of the film achieved during the curing step more stably for a long period of time.

In addition, a step of winding the cooled cured film using a winder may be carried out.

In such an event, the ratio of the transferring speed of the gel sheet on the belt at the time of drying to the transferring speed of the cured film at the time of winding is 1:0.95 to 1:1.40. Specifically, the ratio of the transferring speeds may be 1:0.99 to 1:1.20, 1:0.99 to 1:1.10, or 1:1.0 to 1:1.05, but it is not limited thereto.

If the ratio of the moving speeds is outside the above range, the mechanical properties of the cured film may be impaired, and the flexibility and elastic properties may be deteriorated.

In the process for preparing a polyamide-imide-based film, the thickness deviation (%) according to the following Equation 1 may be 3% to 30%. Specifically, the thickness deviation (%) may be 5% to 20%, but it is not limited thereto.

$$Thickness variation ( \% ) = ( M 1 - M 2 ) / M 1 \times 100 \qquad [ Equation 1 ]$$

In Equation 1, M1 is the thickness (μm) of the gel sheet, and M2 is the thickness (μm) of the cooled cured film at the time of winding.

The polyamide-imide-based film is prepared by the preparation process as described above such that it is excellent in optical and mechanical properties, as well as ultraviolet ray blocking rates. The polyamide-imide-based film may be applicable to various uses that require transparency. For example, the polyamide-imide-based film may be applied to not only display devices but also solar cells, semiconductor devices, sensors, and the like. In particular, since the polyamide-imide-based film according to an embodiment is free of fluorine atoms that may be subject to environmental regulations, it can be utilized in a wider range of applications.

Details on the polyamide-imide-based film prepared by the process for preparing a polyamide-imide film are as described above.

### EMBODIMENTS FOR CARRYING OUT THE INVENTION

Hereinafter, the above description will be described in detail by referring to examples. However, these examples are set forth to illustrate the present invention, and the scope of the present invention is not limited thereto.

### Example 1

A 1-liter glass reactor equipped with a temperature-controllable double jacket was charged with 516.0 g of dimethylacetamide (DMAc) at 20° C. under a nitrogen atmosphere. Then, 46.7 g (0.22 mole) of 2,2′-dimethylbenzidine (m-Tolidine) as a diamine compound was slowly added thereto for dissolution thereof. Thereafter, 8.6 g (0.044 mole) of 1,2,3,4-cyclobutanetetracarboxylic dianhydride (CBDA) as a dianhydride compound was slowly added, followed by stirring for 1 hour. Then, as a dicarbonyl compound, 13.4 g (0.066 mole) of terephthaloyl chloride (TPC) was added, followed by stirring for 1 hour; and 22.33 g (0.11 mole) of isophthaloyl chloride (IPC) was added, followed by stirring for 1 hour, thereby preparing a polymer solution. The polymer solution thus obtained was coated onto a glass plate and then dried with hot air at 80° C. for 30 minutes. It was detached from the glass plate, fixed to a pin frame, and treated in a temperature range of 80° C. to 300° C. at a temperature elevation rate of 2° C./minute to obtain a polyamide-imide film having a thickness of 50 μm.

The specific composition and molar ratio of the polyamide-imide-based polymer are described in the Preparation Example of Table 1 below.

### Examples 2 to 6 and Comparative Examples 1 to 6

Films were each prepared in the same manner as in Example 1, except that the composition and molar ratio of the polymer were changed as shown in Table 1 below.

In Comparative Example 1, when terephthaloyl chloride (TPC) was added and stirred for 1 hour, a white powder precipitate was formed in the solution, making the subsequent procedures impossible.

Further, in Comparative Examples 3 and 5, the viscosity was not increased to the target viscosity for film forming upon completion of the polymerization, so that the subsequent film forming process could not proceed.

### <Preparation Example> Composition of a Polymer

TABLE 1

| | Polymerization ratio of the polyamide-imide-based polymer | | |
|---|---|---|---|
| | Diamine | Dianhydride | Dicarbonyl |
| | compound | compound | compound |
| | (molar ratio) | (molar ratio) | (molar ratio) |
| Ex. 1 | m-Tolidine 100 | CBDA 20 | TPC 30 |
| | | | IPC 50 |
| Ex. 2 | m-Tolidine 100 | CBDA 15 | TPC 30 |
| | | | IPC 55 |
| Ex. 3 | m-Tolidine 100 | CBDA 35 | TPC 15 |
| | | | IPC 50 |
| Ex. 4 | m-Tolidine 100 | CBDA 13 | TPC 37 |
| | | | IPC 50 |
| Ex. 5 | m-Tolidine 100 | CBDA 13 | TPC 57 |
| | | | IPC 30 |
| Ex. 6 | m-Tolidine 100 | CBDA 3 | TPC 69 |
| | | | IPC 28 |
| C. Ex. 1 | m-Tolidine 100 | CBDA 7 | TPC 71 |
| | | | IPC 22 |
| C. Ex. 2 | m-Tolidine 100 | CBDA 100 | — |
| C. Ex. 3 | m-Tolidine 100 | CBDA 41 | TPC 19 |
| | | | IPC 40 |
| C. Ex. 4 | m-Tolidine 100 | 6FDA 100 | — |
| C. Ex. 5 | TFMB 100 | CBDA 100 | — |
| C. Ex. 6 | TFMB 100 | 6FDA 10 | TPC 70 |
| | | | IPC 20 |

### EVALUATION EXAMPLE

The films prepared in the Examples and Comparative Examples were each measured and evaluated for the following properties. The results are shown in Table 2 below.

### Evaluation Example 1: Measurement of Film Thickness

The thickness was measured at 5 random points using a digital micrometer 547-401 manufactured by Mitutoyo Corporation. Their average value was taken as the thickness.

### Evaluation Example 2: Measurement of Transmittance and Haze

The total light transmittance and haze were measured using a haze meter NDH-5000W manufactured by Nippon Denshoku Kogyo in accordance with the JIS K 7105 standard.

### Evaluation Example 3: Measurement of Yellow Index

The yellow index (YI) was measured with a spectrophotometer (UltraScan PRO, Hunter Associates Laboratory) under the conditions of d65 and 10° in accordance with the ASTM-E313 standard.

### Evaluation Example 4: Measurement of Modulus

A sample was cut out by at least 10 cm in the direction perpendicular to the main shrinkage direction of the film and by 10 mm in the main shrinkage direction. It was fixed by the clips disposed at an interval of 10 cm in a universal testing machine UTM 5566A of Instron. A stress-strain curve was obtained until the sample was fractured while it was stretched at a rate of 10 mm/minute at room temperature. The slope of the load with respect to the initial strain on the stress-strain curve was taken as the modulus (GPa).

### Evaluation Example 5: Measurement of Transmittance at a Wavelength of 380 Nm

The transmittance at a wavelength of 380 nm was measured using a UV/visible/near-Infrared spectrophotometer V-670 from JASCO.

TABLE 2

| | Evaluation Example | | | | | |
|---|---|---|---|---|---|---|
| | Thickness | Transmittance | | Yellow | Modulus | Transmittance at a |
| | (μm) | (%) | Haze (%) | index | (GPa) | wavelength of 380 nm (%) |
| Ex. 1 | 50 | 86.8 | 0.14 | 3.81 | 6.04 | 0.24 |
| Ex. 2 | 50 | 86.7 | 0.14 | 3.84 | 6.33 | 0.27 |
| Ex. 3 | 50 | 86.6 | 0.15 | 3.76 | 6.02 | 0.28 |
| Ex. 4 | 50 | 86.4 | 0.16 | 4.01 | 6.54 | 0.22 |
| Ex. 5 | 50 | 86.1 | 0.18 | 4.2 | 6.64 | 0.25 |
| Ex. 6 | 50 | 85.8 | 0.23 | 4.42 | 6.81 | 0.19 |
| C. Ex. 1 | After the addition of TPC, crystallization occurred | | | | | |
| C. Ex. 2 | 50 | 76.5 | 25.1 | 13.1 | 4.3 | 0.18 |
| C. Ex. 3 | Since the viscosity did not reach the target, film forming was not possible | | | | | |
| C. Ex. 4 | 50 | 88.6 | 0.1 | 27 | 4.2 | 0.14 |
| C. Ex. 5 | Since the viscosity did not reach the target, film forming was not possible | | | | | |
| C. Ex. 6 | 50 | 88.1 | 0.18 | 3.2 | 6.1 | 37.6 |

Referring to Table 2, the films according to the examples were excellent in optical properties such as transmittance, haze, and yellow index, as well as excellent in modulus. Further, the transmittance at a wavelength of 380 nm was low, so that the ultraviolet rays blocking performance was excellent.

Explanation of Reference Numerals

| | |
|---|---|
| 100: polyamide-imide-based film | |
| 101: first side | 102: second side |
| 200: functional layer | 300: cover window |
| 400: display unit | 500: adhesive layer |

1. A polyamide-imide-based film, which comprises a polyamide-imide-based polymer that is free of fluorine atoms, wherein the polyamide-imide-based film has a modulus of 5 GPa or more based on a film thickness of 50 μm.

2. The polyamide-imide-based film of claim 1, which has a transmittance of 3% or less at a wavelength of 380 nm based on a film thickness of 50 μm.

3. The polyamide-imide-based film of claim 1, which has a total light transmittance of 80% or more as measured in the visible light wavelength range, a haze of 1% or less, and a yellow index of 5 or less, based on a film thickness of 50 μm.

4. The polyamide-imide-based film of claim 1, wherein the polyamide-imide-based polymer comprises an imide-based repeat unit and an amide-based repeat unit at a molar ratio of 2:98 to 40:60.

5. The polyamide-imide-based film of claim 1, wherein the polyamide-imide-based polymer is a polymer of a diamine compound, a dianhydride compound, and a dicarbonyl compound,
the diamine compound is represented by the following Formula 1,
the dianhydride compound is represented by the following Formula 2, and
the dicarbonyl compound is represented by the following Formula 3: 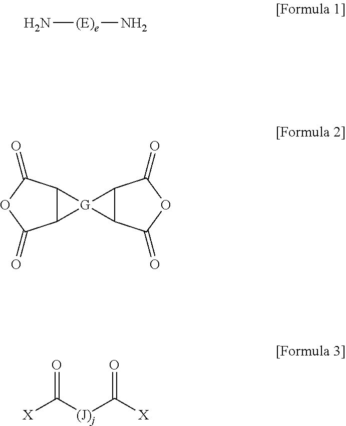
in the above Formulae 1 to 3, E and J are each independently selected from a substituted or unsubstituted divalent C₆-C₃₀ aliphatic cyclic group, a substituted or unsubstituted divalent C₄-C₃₀ heteroaliphatic cyclic group, a substituted or unsubstituted divalent C₆-C₃₀ aromatic cyclic group, a substituted or unsubstituted divalent C₄-C₃₀ heteroaromatic cyclic group, a substituted or unsubstituted C₁-C₃₀ alkylene group, a substituted or unsubstituted C₂-C₃₀ alkenylene group, a substituted or unsubstituted C₂-C₃₀ alkynylene group, —O—, —S—, —C(═O)—, —CH(OH)—, —S(═O)₂—, —Si(CH₃)₂—, and —C(CH₃)₂—,
e and j are each independently selected from integers of 1 to 5,
when e is 2 or more, then the two or more Es are the same as, or different from, each other,
when j is 2 or more, then the two or more Js are the same as, or different from, each other,
G is a group selected from a substituted or unsubstituted tetravalent C₄-C₃₀ aliphatic cyclic group, a substituted or unsubstituted tetravalent C₄-C₃₀ heteroaliphatic cyclic group, a substituted or unsubstituted tetravalent C₆-C₃₀ aromatic cyclic group, or a substituted or unsubstituted tetravalent C₄-C₃₀ heteroaromatic cyclic group, wherein the aliphatic cyclic group, the heteroaliphatic cyclic group, the aromatic cyclic group, or the heteroaromatic cyclic group is present alone, is fused to each other to form a condensed ring, or is bonded by a bonding group selected from a substituted or unsubstituted C₁-C₃₀ alkylene group, a substituted or unsubstituted C₂-C₃₀ alkenylene group, a substituted or unsubstituted C₂-C₃₀ alkynylene group, —O—, —S—, —C(═O)—, —CH(OH)—, —S(═O)₂—, —Si(CH₃)₂—, and —C(CH₃)₂—, and
X is a halogen atom.

6. The polyamide-imide-based film of claim 5, wherein the diamine compound comprises 2,2′-dimethylbenzidine (m-Tolidine).

7. The polyamide-imide-based film of claim 5, wherein the dianhydride compound comprises 1,2,3,4-cyclobutanetetracarboxylic dianhydride (CBDA).

8. The polyamide-imide-based film of claim 1, wherein the polyamide-imide-based polymer comprises an imide-based repeat unit, a first amide-based repeat unit, and a second amide-based repeat unit, and when the sum of the imide-based repeat unit, the first amide-based repeat unit, and the second amide-based repeat unit is 100% by mole, the molar ratio of the first amide-based repeat unit is 70% by mole or less.

9. The polyamide-imide-based film of claim 8, wherein the first amide-based repeat unit is derived from a first dicarbonyl compound, and the second amide-based repeat unit is derived from a second dicarbonyl compound, and
wherein the angle between the two carbonyl groups contained in the first dicarbonyl compound is greater than the angle between the two carbonyl groups contained in the second dicarbonyl compound.

10. The polyamide-imide-based film of claim 1, which has a pencil hardness of HB or higher.

11. A cover window for a display device, which comprises a polyamide-imide-based film and a functional layer, wherein the polyamide-imide-based film comprises a polyamide-imide-based polymer that is free of fluorine atoms, and the polyamide-imide-based film has a modulus of 5 GPa or more based on a film thickness of 50 μm.

12. A display device, which comprises a display unit; and a cover window disposed on the display unit,
wherein the cover window comprises a polyamide-imide-based film and a functional layer, and
wherein the polyamide-imide-based film comprises a polyamide-imide-based polymer that is free of fluorine atoms, and the polyamide-imide-based film has a modulus of 5 GPa or more based on a film thickness of 50 μm.

13. A process for preparing the polyamide-imide-based film of claim 1, which comprises:
polymerizing a diamine compound, a dianhydride compound, and a dicarbonyl compound in an organic solvent to prepare a polyamide-imide-based polymer solution;
casting the solution and then drying it to prepare a gel sheet; and
thermally treating the gel sheet.

14. The process for preparing the polyamide-based film according to claim 13, wherein the step of preparing the polymer solution comprises controlling the viscosity of the polymer solution to 100,000 cps to 500,000 cps at room temperature.
